(19) United States
(12) Patent Application Publication
(10) Pub. No.: US 2020/0152559 A1
(43) Pub. Date: May 14, 2020

(54) Device conducive to reduction of parasitic inductance and method for circuit design and assembly

(71) Applicant: REALTEK SEMICONDUCTOR CORPORATION, Hsinchu (TW)

(72) Inventors: CHAO-MIN LAI, Hsinchu City (TW); TANG-HUNG CHANG, Hsinchu City (TW); HAN-CHIEH HSIEH, Hsinchu City (TW)

(21) Appl. No.: 16/666,523

(22) Filed: Oct. 29, 2019

(30) Foreign Application Priority Data
Nov. 8, 2018 (TW) 107139649

(51) Int. Cl. H01L 23/498; H01L 23/64; H01L 23/00; G06F 17/50

(52) U.S. Cl. CPC H01L 23/49816; H01L 23/645; H01L 2924/30107; G06F 17/5077; H01L 24/14

(57) ABSTRACT

Disclosed are a device conducive to reduction of parasitic inductance and a method for circuit design and assembly; the device and method cause less parasitic inductance and are good for circuit performance. The device includes an integrated circuit of ball grid array packaging (BGA IC), a printed circuit board (PCB), and an electronic component. The BGA IC includes solder balls including at least one target ball. The PCB is electrically connected to the BGA IC via the solder balls. The electronic component is set between the BGA IC and the PCB and electrically connected to the at least one target ball, in which the height of the electronic component is lower than the stand-off height of each of the solder balls.

### BACKGROUND OF THE INVENTION

### 1. Field of the Invention

The present invention relates to a device conducive to reduction of parasitic inductance and a method for circuit design and assembly, especially to a device and method inducing less parasitic inductance.

### 2. Description of Related Art

Many electronic products (e.g., set-top box, cellphone, tablet computer) adopt system-on-a-chip (SoC) design. A device of SoC design (hereafter called “the SoC device”) (e.g., an IC) usually includes a CPU/MPU and peripheral circuits and needs several sets of power supply requiring a plurality of voltage-regulation capacitors (e.g., multilayer ceramic capacitors, MLCCs); particularly, the power supply for CPU requires one or more voltage-regulation capacitors of low inductance.

The aforementioned voltage-regulation capacitors are usually fixed onto a backside of a printed circuit board (PCB) by soldering or included in the IC packaging of the aforementioned SoC device. If a voltage-regulation capacitor is set on the backside of the PCB, the voltage-regulation capacitor must electrically connect to the circuits (e.g., CPU) of the SoC device through the vias of the PCB for the regulation of voltage; unfortunately, the vias of the PCB will cause the problem of parasitic inductance which will affect the high-frequency response of the voltage-regulation capacitor and lead to the instability of the CPU's transient voltage. On the other hand, if a voltage-regulation capacitor is included in the IC packaging of the SoC device, the cost of the IC packaging is higher and an extra space in the IC packaging is required for the placement of the voltage-regulation capacitor; moreover, the SoC device of this kind of IC packaging may be taxed at a higher rate in some countries.

### SUMMARY OF THE INVENTION

An object of the present invention is to provide a device conducive to reduction of parasitic inductance and a method for circuit design and assembly as improvements over the prior art.

Another object of the present invention is to provide a device conducive to reduction of parasitic inductance and a method for circuit design and assembly; the device and method cause less parasitic inductance and are good for circuit performance

An embodiment of the device of the present invention includes an integrated circuit of ball grid array packaging (BGA IC), a printed circuit board (PCB), and an electronic component. The BGA IC includes solder balls including at least one target ball. The PCB electrically connects to the BGA IC via the solder balls. The electronic component is set between the BGA IC and the PCB; in other words, the electronic component is set within an orthographic projection range projected by the BGA IC on the PCB. In addition, the electronic component electrically connects to the at least one target ball. Since the electronic component electrically connects to the BGA IC without passing through the vias of the PCB, the influence of the parasitic inductance of the vias is reduced.

An embodiment of the method of the present invention includes the following steps: limiting a stand-off height of each of solder balls of an integrated circuit of ball grid array packaging (BGA IC) to a height higher than a predetermined height, and having a layout of the solder balls include a reserved space including none of the solder balls; selecting an electronic component, in which the height of the electronic component is lower than the predetermined height; setting the electronic component on a printed circuit board (PCB); and connecting the PCB to the BGA IC through the solder balls, in which the electronic component is set between the PCB and the BGA IC and positioned in the reserved space.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows a lateral view of an embodiment of the device of the present invention.

FIG. 2 shows a bottom view of an embodiment of the BGA IC of FIG. 1.

FIG. 3 shows a lateral view of another embodiment of the device of the present invention.

FIG. 4 shows a lateral view of yet another embodiment of the device of the present invention.

FIG. 5 shows a flowchart of an embodiment of the method of the present invention.

FIG. 6 shows a flowchart of another embodiment of the method of the present invention.

FIG. 7 shows a flowchart of yet another embodiment of the method of the present invention.

FIG. 8 shows a flowchart of a further embodiment of the method of the present invention.

### DETAILED DESCRIPTION OF THE PREFERRED EMBODIMENTS

The present invention discloses a device conducive to reduction of parasitic inductance and a method for circuit design and assembly. The device and method cause less parasitic inductance and are good for circuit performance.

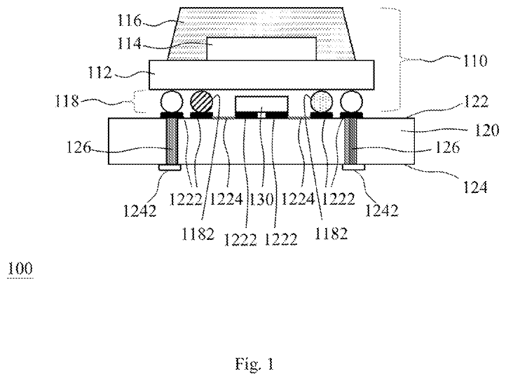

FIG. 1 shows an embodiment of the device of the present invention. The device 100 of FIG. 1 includes an integrated circuit of ball grid array packaging (BGA IC) 110, a printed circuit board (PCB) 120, and an electronic component 130.

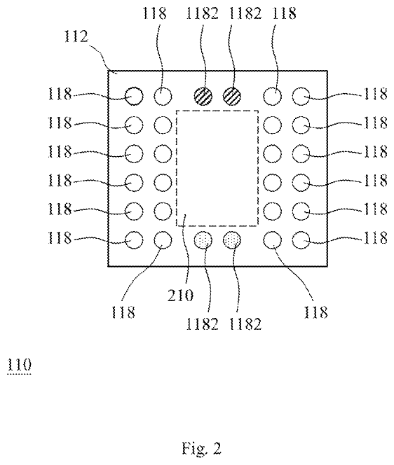

Please refer to FIG. 1. An embodiment of the BGA IC 110 includes a substrate 112, a chip 114, packaging material 116 (e.g., resin), and a plurality of solder balls 118. The chip 114 is electrically connected to the substrate 112 with the technique of wire bonding, the technique of flip chip, or any other known or self-developed techniques suitable for the connection between the chip 114 and the substrate 112, in which the technique of wire bonding and the technique of flip chip are well known in this industrial field. The solder balls 118 includes at least one target ball 1182 such as at least one of a power ball for connection with a power source, a signal ball for connection with a signal source, a ground ball for connection of ground, and balls for other purposes (e.g., for connection with an inductor, a capacitor, an IC, or a voltage/current reference), in which the power ball is used for the supply of a power supply voltage, the signal ball is used for the transmission of a signal, and the ground ball is used for the supply of a ground voltage. In this embodiment, the at least one target ball includes at least one power ball (e.g., the circles with slashes as shown in FIG. 1 and FIG. 2) and at least one ground ball (e.g., the circles with dots as shown in FIG. 1 and FIG. 2). In addition, the layout (a.k.a. distribution pattern) of the solder balls 118 includes a reserved space for the placement of the electronic component 130, in which the reserved space includes none of the solder balls 118. FIG. 2 shows the bottom view of the BGA IC 110 showing the reserved space 210 defined by the layout of the solder balls 118; this reserved space 210 is just exemplary for understanding, not a limitation in the implementation of the present invention.

Please refer to FIG. 1. The PCB 120 includes a first surface 122 and a second surface 124. The first surface 122 includes a plurality of solder joints 1222 (i.e., the black bars of FIG. 1) and traces 1224. The electronic component 130 is set on the first surface 122 and electrically connected with the at least one target ball 1182 via at least one of the solder joints 1222. The PCB 120 is electrically connected with the solder balls 118 via at least a part of the solder joints 1222 and thereby electrically connected with the BGA IC 110. The second surface 124 can optionally include solder joints 1242 and traces (not shown) according to the demand for implementation. The solder joints 1242 of the second surface 124 can be electrically connected to the solder joints 1222, the traces 1224, other solder joints (not shown), or other traces (not shown) through the vias 126 of the PCB 120. It should be noted that the solder joints 1242 and the traces of the second surface and the vias 126 are options for the implementation of the PCB 120. In addition, the PCB 120 should reserve a region of the first surface 122 for the placement of the electronic component 130.

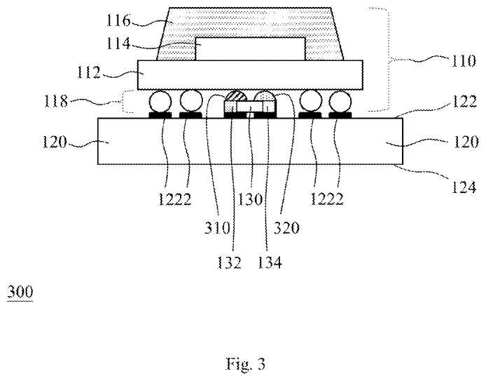

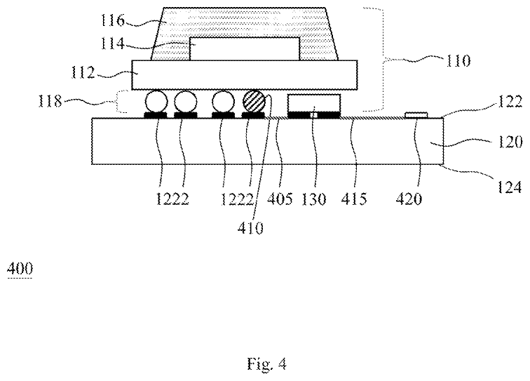

Please refer to FIG. 1. The electronic component 130 is set between the substrate 112 of the BGA IC 110 and the PCB 120; in other words, the electronic component 130 is set within an orthographic projection range projected by the BGA IC 110 on the PCB 120. In this embodiment, the electronic component 130 includes a first terminal and a second terminal; the first terminal is electrically connected to the power ball(s) of the at least one target ball 1182 via at least a part of the solder joints 1222 and the traces 1224; the second terminal is electrically connected to the ground ball(s) of the at least one target ball 1182 via at least a part of the solder joints 1222 and the traces 1224. In another embodiment as the device 300 of FIG. 3, the position of the electronic component 130 and the position of the at least one target ball (i.e., the power ball 310 and the ground ball 320 here) are respectively located in the foreground and background of FIG. 3; a first terminal 132 of the electronic component 130 is electrically connected to the power ball 310 via at least a part of solder joints and traces and a second terminal 134 of the electronic component 130 is electrically connected to the ground ball 320 via at least a part of solder joints and traces, in which the shortest distance between the first terminal 132 and the second terminal 134 is substantially equal to the shortest distance between the center of the power ball 310 and the center of the ground ball 320, and the distance between the first terminal and the power ball 310 is substantially equal to the distance between the second terminal 134 and the ground ball 320. In yet another embodiment, the electronic component 130 is electrically connected to the at least one target ball via one or more electricity-conductive paths (e.g., traces, bonding wires, conductors, . . . ) of the PCB 120. In a further embodiment as the device 400 of FIG. 4, a terminal of the electronic component 130 is electrically connected to the at least one target ball 410 (e.g., at least one power ball) via the trace 405 and another terminal of the electronic component 130 is electrically connected to a target solder joint 420 (e.g., a solder joint for the supply of a ground voltage) on the first surface 122 of the PCB 120, in which the solder joint 420 is not between the BGA IC 110 and the PCB 120 and is outside the aforementioned orthographic projection range. In addition, an embodiment of the electronic component 130 is a passive component; for instance, the electronic component 130 is a capacitor (e.g., multilayer ceramic capacitor, MLCC), an inductor, or a resistor (e.g., an external resistor used for the supply of an accurate reference voltage).

Please refer to FIG. 1. In order to set the electronic component 130 between the BGA IC 110 and the PCB 120, in an exemplary implementation the height of the electronic component 130 does not exceed the stand-off height of each of the solder balls 118, in which the stand-off height is dependent on an IC packaging process of the BGA IC 110 and could be the minimum value within a stand-off height range specified by the IC packaging process. In another exemplary implementation, the height of the electronic component 130 is not higher than the vertical distance between the substrate 112 of the BGA IC 110 and the first surface 122 of the PCB 120; in consideration of the solder paste applied to the solder balls and the pads of the electronic component 130, the maximum height of the electronic component 130 can be limited to a height lower than the minimum among the heights of the solder balls 118. For instance, providing the stand-off height of each of the solder balls 118 is usually not higher than a designed diameter for each of the solder balls 118 while the designed diameter is dependent on the aforementioned IC packaging process, the height of the electronic component 130 can be limited to the designed diameter. The IC packaging process of the BGA IC 110 and the surface mount technology for the BGA IC 110 can be known or self-developed techniques.

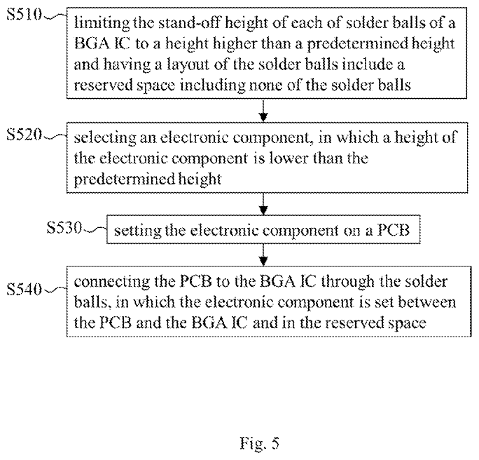

FIG. 5 shows the method for circuit design and assembly according to an embodiment of the present invention. FIG. 5 includes the following steps:
step S510: limiting the stand-off height of each of solder balls of a BGA IC to a height higher than a predetermined height and having a layout of the solder balls include a reserved space including none of the solder balls. In an exemplary implementation, the predetermined height is not higher than a designed diameter for each of the solder balls while the designed diameter is dependent on an IC packaging process of the BGA IC; for instance, the predetermined height is between 40% and 70% of the designed diameter.
step S520: selecting an electronic component, in which the height of the electronic component is lower than the predetermined height. In an exemplary implementation, the electronic component is a passive component such as a capacitor (e.g., MLCC), an inductor, or a resistor. In another implementation, the electronic component is an active component provided the height of the active component is not higher than the predetermined height and the active component can fit in the reserved space.
step S530: setting the electronic component on a PCB.
step S540: connecting the PCB to the BGA IC through the solder balls, in which the electronic component is set between the PCB and the BGA IC, which means that the electronic component is set within an orthographic projection range projected by the BGA IC on the PCB and the electronic component is positioned in the reserved space.

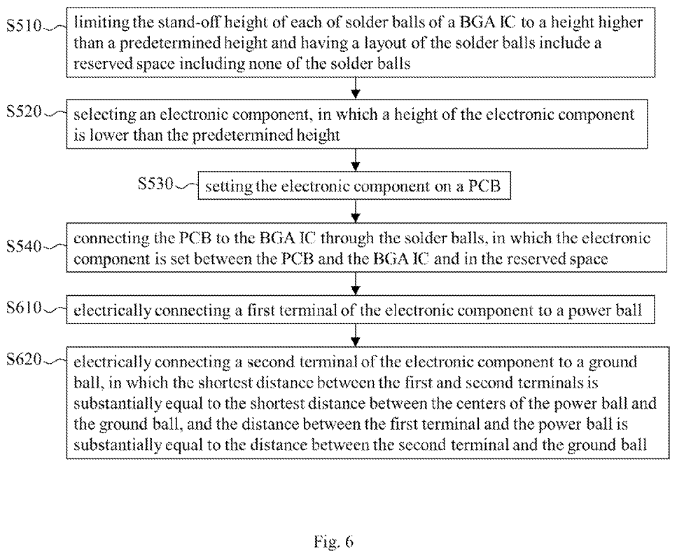

FIG. 6 shows the method for circuit design and assembly according to another embodiment of the present invention. In comparison with FIG. 5, FIG. 6 further includes the following steps:
step S610: electrically connecting a first terminal of the electronic component to a power ball of the solder balls.
step S620: electrically connecting a second terminal of the electronic component to a ground ball of the solder balls, in which the shortest distance between the first terminal and the second terminal is substantially equal to the shortest distance between the center of the power ball and the center of the ground ball, and the distance between the first terminal and the power ball is substantially equal to the distance between the second terminal and the ground ball.

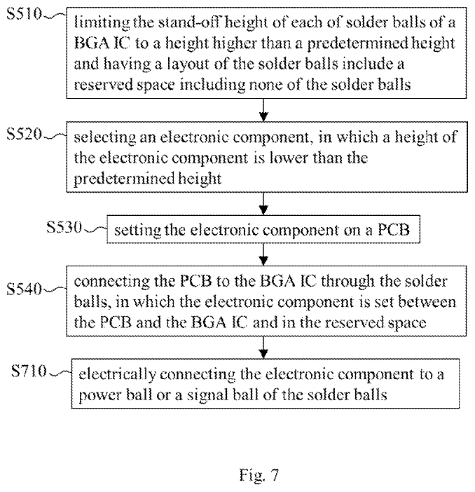

FIG. 7 shows the method for circuit design and assembly according to yet another embodiment of the present invention. In comparison with FIG. 5, FIG. 7 further includes the following steps:
step S710: electrically connecting the electronic component to a power ball or a signal ball of the solder balls.

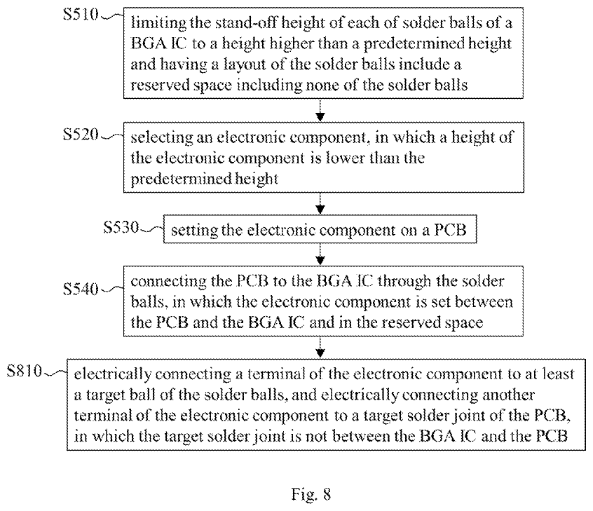

FIG. 8 shows the method for circuit design and assembly according to a further embodiment of the present invention. In comparison with FIG. 5, FIG. 8 further includes the following steps:
step S810: electrically connecting a terminal of the electronic component to at least a target ball of the solder balls, and electrically connecting another terminal of the electronic component to a target solder joint of the PCB, in which the target solder joint is not between the BGA IC and the PCB.

Since people of ordinary skill in the art can appreciate the detail and modification of the method embodiments of FIGS. 5-8 by referring to the disclosure of the device embodiments of FIGS. 1-4, which means that each feature of the device embodiments of FIGS. 1-4 can be applied to the method embodiments of FIGS. 5-8 in a reasonable way, repeated and redundant description is omitted here. It should be noted that the execution order of the steps of each method embodiment could be changed according to the demand for implementation as long as the implementation is practicable.

It should be noted that people of ordinary skill in the art can implement the present invention by selectively using some or all of the features of any embodiment in this specification or selectively using some or all of the features of multiple embodiments in this specification as long as such implementation is practicable, which implies that the present invention can be carried out flexibly.

To sum up, the present invention reserves a region of the layout of solder balls of an BGA IC for the placement of an electronic component and this allows the transmission distance between the electronic component and the BGA solder balls to be decreased. Accordingly, the electronic component is electrically connected to the BGA solder balls without passing through the vias of a PCB, the influence of the parasitic inductance of the vias is reduced, and the circuit performance as a whole is improved.

The aforementioned descriptions represent merely the preferred embodiments of the present invention, without any intention to limit the scope of the present invention thereto. Various equivalent changes, alterations, or modifications based on the claims of present invention are all consequently viewed as being embraced by the scope of the present invention.

What is claimed is:

1. A device conducive to reduction of parasitic inductance, comprising:
an integrated circuit of ball grid array packaging (BGA IC) including solder balls which include at least one target ball;
a printed circuit board (PCB) electrically connected to the BGA IC via the solder balls; and
an electronic component set between the BGA IC and the PCB, and the electronic component electrically connected to the at least one target ball.

2. The device conducive to reduction of parasitic inductance of claim 1, wherein the at least one target ball includes at least one of a power ball for connection with a power source, a signal ball for connection with a signal source, a ground ball for connection of ground, and a ball for connection with an inductor, a capacitor, an IC, a voltage reference, or a current reference.

3. The device conducive to reduction of parasitic inductance of claim 1, wherein the at least one target ball includes a power ball for connection with a power source and a ground ball for connection with ground.

4. The device conducive to reduction of parasitic inductance of claim 1, wherein the electronic component is a passive component or an active component.

5. The device conducive to reduction of parasitic inductance of claim 4, wherein the passive component is a capacitor, an inductor, or a resistor.

6. The device conducive to reduction of parasitic inductance of claim 5, wherein the passive component is a multiplayer ceramic capacitor (MLCC).

7. The device conducive to reduction of parasitic inductance of claim 1, wherein a height of the electronic component is lower than a stand-off height of each of the solder balls.

8. The device conducive to reduction of parasitic inductance of claim 1, wherein a height of the electronic component is not more than a designed diameter of each of the solder balls.

9. The device conducive to reduction of parasitic inductance of claim 1, wherein the PCB includes first solder joints positioned on a first surface of the PCB, the first solder joints are electrically connected to a first part of the solder balls, the first part of the solder balls includes the at least one target ball, and the electronic component is set on the first surface of the PCB and electrically connected to the at least one target ball via at least one of the first solder joints.

10. The device conducive to reduction of parasitic inductance of claim 9, wherein the PCB includes second solder joints positioned on a second surface of the PCB, the second solder joints are electrically connected to a second part of the solder balls via a plurality of vias of the PCB, and the second part of the solder balls does not include the at least one target ball.

11. The device conducive to reduction of parasitic inductance of claim 1, wherein the electronic component includes a first terminal and a second terminal, the at least one target ball includes a power ball for connection with a power source and a ground ball for connection with ground, the first terminal is electrically connected to the power ball, the second terminal is electrically connected to the ground ball, a shortest distance between the first terminal and the second terminal is substantially equal to a shortest distance between a center of the power ball and a center of the ground ball.

12. The device conducive to reduction of parasitic inductance of claim 1, wherein a terminal of the electronic component is electrically connected to the at least one target ball, another terminal of the electronic component is electrically connected to a target solder joint of the PCB, and the target solder joint is not between the BGA IC and the PCB.

13. The device conducive to reduction of parasitic inductance of claim 12, wherein the at least one target ball is a power ball for connection with a power source and the target solder joint is for connection with ground.

14. A method for circuit design and assembly, comprising:
limiting a stand-off height of each of solder balls of an integrated circuit of ball grid array packaging (BGA IC) to a height higher than a predetermined height, and having a layout of the solder balls include a reserved space including none of the solder balls;
selecting an electronic component, in which a height of the electronic component is lower than the predetermined height;
setting the electronic component on a printed circuit board (PCB); and
connecting the PCB to the BGA IC through the solder balls, in which the electronic component is set between the PCB and the BGA IC and positioned in the reserved space.

15. The method for circuit design and assembly of claim 14, wherein the predetermined height is between 40% and 70% of a designed diameter of the solder balls.

16. The method for circuit design and assembly of claim 14, wherein the electronic component is a passive component or an active component.

17. The method for circuit design and assembly of claim 16, wherein the passive component is a capacitor, an inductor, or a resistor.

18. The method for circuit design and assembly of claim 14, wherein the electronic component includes a first terminal and a second terminal, the solder balls include a power ball for connection with a power source and a ground ball for connection with ground, and the method further comprises: electrically connecting the first terminal to the power ball;
and electrically connecting the second terminal to the ground ball, in which a shortest distance between the first terminal and the second terminal is substantially equal to a shortest distance between a center of the power ball and a center of the ground ball.

19. The method for circuit design and assembly of claim 14, further comprising: electrically connecting the electronic component to a power ball or a ground ball among the solder balls.

20. The method for circuit design and assembly of claim 14, further comprising: electrically connecting a terminal of the electronic component to at least one target ball of the solder balls; and electrically connecting another terminal of the electronic component to a target solder joint of the PCB, in which the target solder joint is not between the BGA IC and the PCB.
